(19) United States
(12) Patent Application Publication
(10) Pub. No.: US 2013/0307013 A1
(43) Pub. Date: Nov. 21, 2013

(54) LIGHT EMITTING DEVICE WITH DARK LAYER

(71) Applicants: Bit Tie Chan, Penang (MY); Keat Chuan Ng, Penang (MY); Kiam Soon Ong, Penang (MY)

(72) Inventors: Bit Tie Chan, Penang (MY); Keat Chuan Ng, Penang (MY); Kiam Soon Ong, Penang (MY)

(73) Assignee: AVAGO TECHNLOGIES ECBU IP (SINGAPORE) PTE. LTD., SINGAPORE (SG)

(21) Appl. No.: 13/472,285

(22) Filed: May 15, 2012

(51) Int. Cl. H01L 33/48

(52) U.S. Cl. 257/99; 257/E33.056; 257/E33.058

(57) ABSTRACT

A light-emitting device having a plurality of leads, a body, a light source die, a dark layer, and a substantially transparent encapsulant is disclosed. The dark layer absorbs a substantial portion of ambient light. The light source die may be a top emitting die. The light-emitting devices may be suitable for applications such as a large scale electronic display where each pixel is represented by each light-emitting device. The dark layer may contribute towards high contrast ratio by absorbing substantial amount of ambient light falling thereon.

### BACKGROUND

Light emitting diodes (herein after LEDs) have many advantages over conventional light sources, such as incandescent, halogen and fluorescent lamps. These advantages include longer operating life, lower power consumption and smaller size. Consequently, LEDs have been widely used in many applications, such as flashlights, traffic signals, automotive tail lights and display devices.

Due to the small form factor, LEDs are widely used in large-scale electronic display systems, which may be found in stadiums, discotheques, electronic traffic sign displays and infotainment boards along streets. The large-scale electronic displays may be configured to display text, graphics, images or videos containing information or entertainment content. Most of these electronic display systems are placed outdoors and thus always viewed by users from a distance ranging from a few to more than one hundred meters. Therefore, unlike home use flat screens and computer monitors that use Liquid Crystal Display technology (referred hereinafter as LCD), each pixel of these outdoor display systems is represented by at least a light source, usually an LED or a group of LEDs. Contrary to LCD panels that cut off light through color filters, the light emitted from the LEDs in outdoor electronic displays typically is not blocked or modulated further, thus achieving high power efficiency.

Most of these large-scale display systems comprise hundreds or thousands of LEDs arranged in a two dimensional plane, usually in a matrix arrangement. The LEDs in the display system may be a white LEDs or a tri-color RGB. Each LED may represent a pixel in the electronic display but in some occasions, a group of single colored LEDs may represent one pixel. The form factor and design of the LEDs may play a role in picture quality displayed by electronic display systems. For example, for electronic display systems that require high resolution, the LEDs are preferably as small as possible so that more LEDs can be placed into a limited space to represent more pixels per unit area. Another feature of LEDs affecting the electronic display quality is brightness of the LEDs. To be viewable from a distance, the LEDs are required to produce more cavity per unit area.

Contrast ratio is one parameter for comparing the electronic display systems. The contrast ratio is a property of a display system, which may be related to the ratio of the luminance of the brightest color to that of the darkest color that the system is capable of producing. A high contrast ratio is a desired aspect for the electronic display systems. Consider an example of an electronic system having at least first and second light-emitting devices. Each of the light-emitting devices represents one pixel of the display, wherein the second light-emitting device is configured to produce maximum output, Φ_{O} representing the brightest color, and the second light-emitting device is configured to produce no output, representing the darkest color of the display. As the second light-emitting device produces no output and the display is used in a bright area where reflection is significant, the brightness perceived by a user may be related to the ambient brightness reflected from the second light-emitting device, Φ_{R}. Ideally, the contrast ratio may be modeled as related to equation (1), wherein Φ_{O} represents the brightness of the brightest color whereas O_{R} represents the ambient brightness reflected from the surrounding darkest light-emitting device.

Contrast Ratio=Φ_{O}/Φ_{R} (1)

From equation (1), there may be more than one way to increase contrast ratio. One way may be to increase Φ_{O}, which would mean increasing the brightness of light-emitting devices by using high power dies or using a packaging for the light-emitting device capable of extracting more light. As will be discussed in greater detail subsequently herein, another way to increase contrast ratio may be via reducing Φ_{R}, by reducing the reflection of ambient light from the surrounding darkest light-emitting device.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements. The drawings are for illustrative purpose to assist understanding and may not be drawn per actual scale.

FIG. 1A illustrates a cross-sectional view of a light-emitting device;

FIG. 1B illustrates a top view of the light-emitting device shown in FIG. 1A;

FIG. 1C illustrates a cross-sectional view of the light-emitting device shown in FIG. 1B along line 3-3;

FIG. 2A illustrates a cross-sectional view of a light-emitting device partially covered by a dark layer;

FIG. 2B illustrates a top view of the light-emitting device shown in FIG. 2A;

FIG. 3A illustrates a cross-sectional view of a light-emitting device having a substrate;

FIG. 3B illustrates a top view of the light-emitting device shown in FIG. 3A;

FIG. 4A illustrates a cut-away cross-sectional view of an electronic display; and

FIG. 4B illustrates a top view of the electronic display shown in FIG. 4A.

### DETAILED DESCRIPTION

Light-emitting devices may be implemented using various packaging technologies such as a plastic leaded chip carrier (herein after PLCC) package, a ball grid array package (herein after BGA), a pin grid array package (herein after PGA), a quad flat pack (herein after QFP), a printed circuit board (herein after PCB) package and so on. Certain packages, for example PLCC packages, may comprise a lead frame over a molded polymer materials such as Polyphthalamide (herein after PPA), Polyamide or Epoxy resin encapsulant like MG 97. For surface mount type, leads extending from the lead frame may be bent so that the light-emitting devices can be soldered on a substrate without through-holes. Light-emitting devices based on other packaging technologies such as a BGA and PGA may comprise a substrate having conductive traces without a lead frame. Although a particular type of package is illustrated in each embodiment hereinafter, the features described may be applicable to other embodiments and other types of packaging technologies,

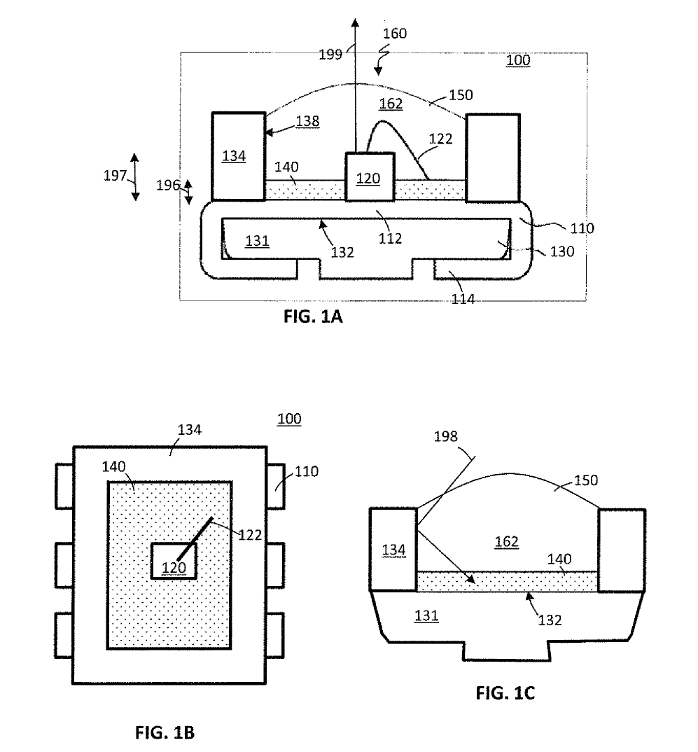

FIG. 1A illustrates an embodiment of a light-emitting device 100 shown in a cross-sectional view. A top view of the light-emitting device 100 is shown in FIG. 1B. FIG. 1C illustrate another cross-sectional view of the light-emitting device 100 along line 3-3 shown in FIG. 1B. The light-emitting device 100 may comprise a plurality of leads 110, a light source die 120, a body 130, a dark layer 140 and an encapsulant 150 encapsulating the light source die 120. As will be clear from the description and drawings, “body” as used herein in reference to a component of a light-emitting device refers to the primary structure which provides structural support for other components of the light emitting device. In another embodiment, the body 130 may be a substrate (not shown) such as a PCB.

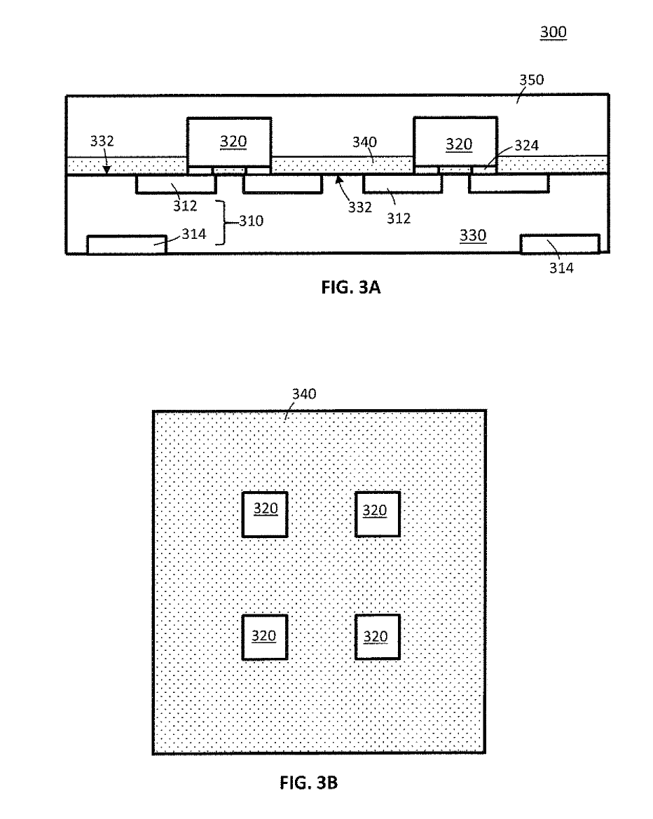

Similarly, “leads” 110 or “conductors”as used herein in reference to the light-emitting device refers to the means for electrically connecting the light-source die 120 to an external light source (not shown). In PLCC packages, leads 110 forming part of a lead frame is utilized but in another packaging technologies, for example a PCB, electrically conductive traces or conductors (not shown) may be utilized. The scope of the invention should not be limited to any specific forms illustrated, but should be taken into consideration various other technologies, other forms of packaging either presently available, or developed in future. For example, the leads 110 mentioned in the specification should include conductive traces 310 (see FIG. 3A), and the body 130 mentioned in the specification should include a substrate 330 (See FIG. 3A).

In the embodiment shown in FIGS. 1A and 1B, the plurality of conductors or leads 110 may be made of electrically and thermally conductive material, such as steel, copper, metal or a metal alloy, a metal compound or other similar material. The plurality of leads 110 may be formed using any conventional stamping, cutting, etching or other similar process that is known in the art. For surface mount purposes, the leads 110 may be bent to define a bottom portion 114 for attaching to external surfaces (not shown). A portion 112 of the lead may be made larger to define a die attach pad to receive the light source die 120. The light source die 120 may be connected to the plurality of leads 110 through a wire bond 122. The wire bond 122 may be a gold, copper or other similar wire bond material. The light source die 120 may be connected to the plurality of leads 110 through solder balls using flip chip technology in another embodiment without any wire bonds. In yet another embodiment, other forms of electrical connection or combinations of wire bonds and solder balls may be used.

The light source die 120 may be mounted on a portion 112 of one of the leads 110. The light source die 120 may be configured to generate light in response to applied drive current, and may be connected to an external supply through the leads 110. The light source die 120 may be an LED die, a laser diode die, or other light source capable of emitting light. The light emitted from the light source die 120 may be visible light such as white or other colored visible light, as well as invisible light such as infra-red light and ultra-violets light.

The light-emitting device 100 illustrated in FIG. 1 is shown as having only a single light source die 120. In another embodiment, the light-emitting device 100 may have a plurality of dies 120 to produce more light or light having different wavelengths, depending on the application. For example, a light-emitting device 100 for use in an outdoor color display in a stadium may comprise two green, one red and one blue light source dies 120. In another embodiment, the light-emitting device 100 may comprise three white light source dies 120 in order to obtain higher light intensity.

As shown in the embodiment in FIGS. 1A-1C, the body 130 of the light-emitting device 100 may comprise a base portion 131 and at least one sidewall 134. The base portion 131 may be part of the body 130 in direct contact with the plurality of leads 110. In another embodiment, the base portion 131 may be a PCB. The base portion 131 may define a surface 132 for accommodating the plurality of leads 110 and the light source die 120. A portion of the surface 132 may be covered by a portion of the leads 110 as shown in FIG. 1A but at another location where the surface 132 is not covered by the leads 110, the dark layer 140 may be in direct contact with the surface 132 as shown in FIG. 1C. The at least one sidewall 134 may define an inner surface 138. The light-emitting device 100 may comprise a cavity 162 defined by the at least one sidewall 134 and the surface 132. An aperture 160 may be directly connecting the cavity externally for light emission. For example, light emitted from the light source die 120 may be configured to emit through the aperture 160.

The cavity 162 of the light-emitting device 100 may be filled with a layer of encapsulant 150 for protecting the light source die 120 and the wire bonds 122. The encapsulant 150 may be an epoxy, a polymer, silicone, or other similar substantially transparent material that may be injected into the cavity 162 of the light-emitting device 100 encapsulating the light source die 120, the dark layer 140 and the surface 131. In another embodiment, the encapsulant 150 may further contain a wavelength converting material or a luminescent material (not shown), such as a phosphor to convert the light generated by the light source dies 120 to light having a different spectrum.

The body 130 having the base portion 131, and the at least one side wall 134 may be an integral single piece structure. The body 130 may be formed using an opaque material such as a polyphthalamide (referred hereinafter as PPA), polyimide, epoxy resin, plastic and other similar material. In another embodiment, the body 130 may be epoxy or silicone that is transparent. The body 130 may be formed on the lead 110 using an injection molding process or other known process. (The lead 110 may be connected to a lead frame, not shown.) Alternatively, the body 130 may be pre-formed and subsequently assembled to form the light-emitting device 100. In another embodiment, the body 130 may be a substrate (not shown) such as a PCB with structures defining the at least one sidewall 134 glued or attached in some other methods onto the substrate (not shown).

The body 130 may be highly reflective, or coated with a reflective material. For example, a light-emitting device 100 having a white PPA may achieve reflectivity of light more than 90%. In some cases, the body 130 may be less reflective having black plastic or other black colored material. Generally, a body 130 having high reflectivity may improve light output but a highly reflective body 130 may also reflect ambient light or light from other sources (not shown) falling on the body 130. In order to minimize reflection of ambient light, the at least one sidewall 134 may be arranged such that the inner surface 138 may be substantially perpendicular to the plane of the surface 132 or the base portion 131 as shown in FIG. 1A and FIG. 1C. Ambient light may illuminate from a specific top direction. Accordingly, the inner surface 138 being perpendicular to the surface 131 may direct the ambient light from the top direction towards the dark layer 140 as illustrated by ray 198 in FIG. 1C.

In the embodiment shown in FIGS. 1A-1C, the light-emitting device 100 comprises a dark layer 140 characterized by a dark visual appearance and arranged within the cavity 162 adjacent to the light source die 120 on the base portion 131 of the body 130. In one embodiment, the dark visual appearance may be a black color absorbing more than 90% of light falling onto the dark layer 140. The dark layer 140 may be arranged for substantially occluding the base portion 131 from light falling thereon. The dark layer 140 may be arranged for substantially inhibiting reflection by the base portion 131.

In another embodiment, the body 130, and more particularly the base portion 131, may be made from black material and the dark visual appearance may be black. In such case, since the base portion 131 may be black, the dark layer 140 may be arranged without substantially occluding the base portion 131 from light falling thereon. However, arrangement of the dark layer 140 may substantially occlude light from falling on the plurality of leads 110 in another embodiment. The dark layer 140 may be arranged for substantially inhibiting reflection by the plurality of leads 110. The dark layer 140 shown in FIG. 1A covers the base portion 131 of the body 130. However, in another embodiment, the dark layer 140 may further cover the inner surface 138 of the at least one sidewall 134, in addition to the base portion 131.

The dark layer 140 may be in direct contact with the light source die 120 as shown in FIG. 1A. The light source die 120 may be a top emitting die, which may avoid light otherwise emitted by die side surfaces from being blocked by the dark layer 140. A top emitting light source die 120 may be configured to emit a substantial portion of light in a top direction, which may be substantially perpendicular to the surface 131 as illustrated by ray 199 in FIG. 1A, which may substantially avoid the light from the light source die being blocked by the dark layer 140. As shown in the embodiment in FIG. 1A, the dark layer may be formed at a bottom portion of the cavity 162, for substantially avoiding any blocking of the light emitted from the light source die 120 by the dark layer 140. In one embodiment, the dark layer 140 may have a thickness 196 that may be less than approximately 40% of the height 197 of the light source die 120.

The dark layer 140 may comprise a dark colored pigment such as black pigment, or a mixture of dark green, red and/or blue pigment. The pigment may be coated on the base portion 131 to form the dark layer. Alternatively, the dark layer 140 may be formed by adding dark colored pigment granules into the encapsulant 150 whereby a dark layer 140 may be formed first prior to forming the transparent encapsulant layer 150 from above the dark layer 140. In another embodiment where the body 130 is substantially dark, the body 130 may be lighter than the dark visual appearance of the dark layer 140. This may be due to dark layer 140 being formed using higher density of dark pigment compared to the body 130.

The optical properties of the body 130 and the dark layer 140 may have an optical design consideration when used in large-scale display application. Consider again the example of an electronic system (not shown) having at least a plurality of identical light-emitting devices 100. Each of the light-emitting devices 100 may represent one pixel of the display. One of the light-emitting devices may be configured to produce maximum output, Φ_{O} representing the brightest color, and the other one of the light-emitting devices may be configured to produce no output, representing the darkest color of the display and the brightness perceived by a user may be based on the ambient brightness, Φ_{R} reflected from the light-emitting device that is turned off.

Recall again from equation (1) that the contrast ratio of the large-scale display (not shown) may be modeled using the ratio of Φ_{O} and Φ_{R}. Increasing the reflectivity of the body 130, particularly the inner surface 138 of the at least one sidewall 134 may increase light output significantly and thus, increasing the maximum light output Φ_{O}. However, any external light falling on the light-emitting devices 100 may be reflected at a higher percentage, and may increase Φ_{R} as well. The contrast ratio might be increased if Φ_{O} increases more than Φ_{R}. The dark layer 140, on the other hand, may reduce light output as the light emitted from the light source die 120 may be configured to absorbed ambient light falling on the dark layer 140 and thus reducing light output Φ_{O}, but may still increase the contrast ratio if the reflection of ambient light may be absorbed in a higher percentage, reducing Φ_{R}.

Some embodiments may employ one or more additional techniques for obtaining high contrast ratio, for example, by having a substantially non-reflective body 130 except that the inner surface 138 may be made reflective. However, as part of such additional techniques, the inner surface 138 may be made perpendicular or slanted at an angle, such that ambient light may be directed to the dark layer 140. As part of such additional techniques, the dark layer 140 may be configured to absorb light as much as possible. As most ambient light may be coming from a top direction as shown by ray 198 in FIG. 1C, the light may be reflected towards the dark layer 140 and may be absorbed thereon. Consequently, reflected ambient light Φ_{R} may be reduced substantially. The light output from the light source die 120 may be directed substantially to the top direction as shown by 199 by using a top-emitting light source die 120 and thus, aspects of such additional high contrast ratio techniques may have little affect reducing the maximum light output Φ_{O} of the light-emitting device 100.

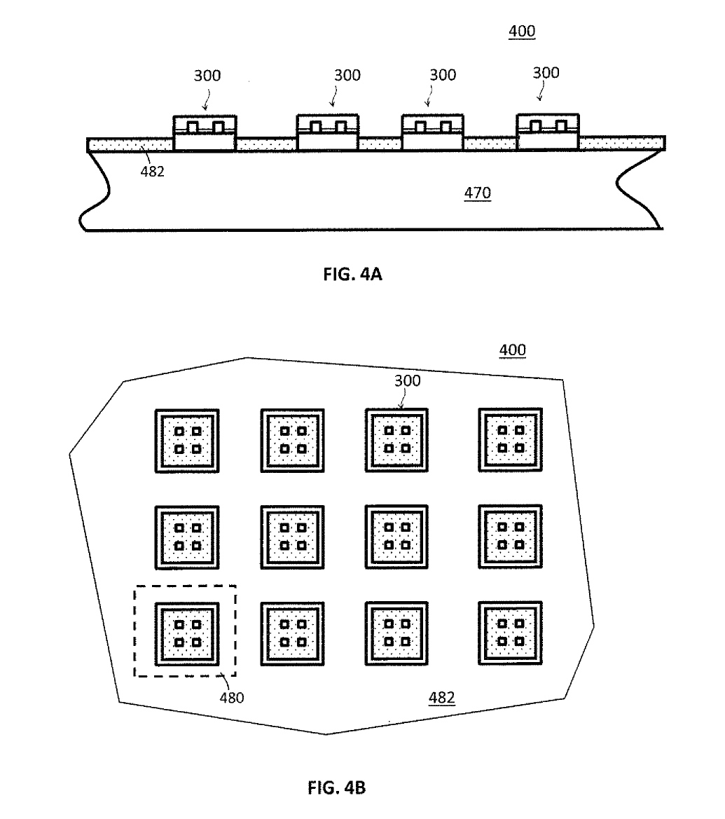

For light-emitting devices having a highly reflective body 130, high contrast ratio may be achieved by covering the base portion 131 of the light-emitting device 100 with the dark layer 140. All outer surfaces of the body 130 may be covered by dark potting material 482 (see FIG. 4A). This arrangement may simplify fabrication and may reduce costs, by avoiding having to coat the inner surface 138 of the at least one sidewall. Coating may be avoided in a case where dark potting material may applied anyway in typical circumstances. Alternatively, the body 130 may be made using less reflective material. The resulting less reflective body 130 may be used in combination with the previously discussed top emitting light source die 120 that emits the substantial portion of light only to the top direction, as illustrated by ray 199.

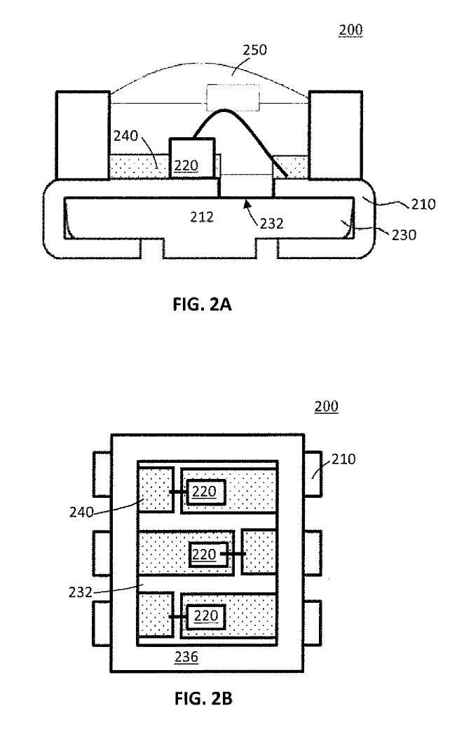

FIG. 2A illustrates an embodiment of a light-emitting device 200 shown in cross-sectional view. A top view of the light-emitting device 200 is shown in FIG. 2B. The light-emitting device 200 may comprise a plurality of leads 210, a plurality of light source dies 220, a body 230, a dark layer 240 and an optional transparent encapsulant 250. The body 230 may define a surface 232. The surface 232 and the body 230 may be characterized by a dark visual appearance. The dark layer 240 in the embodiment shown in FIGS. 2A and 2B may be arranged to cover only the portion of leads 210 formed on the surface 232. The light source dies 220 shown in FIG. 2B may be configured to emit different wavelengths. For example, the light source dies 220 may be configured to produce red, green and blue light respectively.

FIG. 3A illustrates an embodiment a PCB based light-emitting device 300 shown in a cross-sectional view. A top view of the light-emitting device 300 is shown in FIG. 3B. The light-emitting device 300 may comprise a substrate 330, a plurality of conductors 310, at least one or more light source dies 320, a dark layer 340 and a transparent encapsulant 350. The substrate 330 may be configured as a “body” to provide structural support for the entire light-emitting device 300. In the embodiment shown in FIGS. 3A-3B, the “body” or substrate 330 may comprise a PCB. The substrate 330 may comprise a top surface 332. The plurality of conductors 310 exposed on the top surface 332 may be conductive traces 312 that may be configured to received the at least one or more light source dies 320. The conductors 310 located on the opposite surface of the top surface 332 may be solder pads 314 for establishing electrical connection to an external PCB.

The at least one or more light source dies 320 may be flip chip dies that may be attached to the conductive traces 312 through solder balls 324. As shown in FIG. 4B, the light source dies 320 may be arranged in a two dimensional matrix. Two of the dies 320 may be configured to emit green light, and the other dies may be configured to emit red light and blue light accordingly. The dark layer 340 may be adapted to cover the entire top surface 332 of the substrate 330. Alternatively, the dark layer may be configured to cover only the conductive traces 312. The encapsulant 350 may encapsulate the light source dies 320 and the dark layer 340. In the embodiment shown in FIG. 3A, there's no sidewall, so as avoid any reflection of ambient light that may otherwise result if there were a sidewall. Accordingly, since there's no sidewall to reflect ambient light, limited reflection of ambient light may take place only at dark layer 332. Thus, compared to previous embodiments, the arrangement of the dark layer 340 with no sidewall as shown in FIG. 3A may be more effective for improving contrast ratio.

FIG. 4A illustrates an embodiment of an electronic display 400 shown in a cut-away cross-sectional view. A cut-away top view of the electronic display 400 is shown in FIG. 4B. The electronic display 400 may comprise a substrate 470 and a plurality of the light emitting devices 300 as just discussed with respect to FIGS. 3A and 3B. The plurality of light-emitting devices 300 may be employed in the embodiment shown in FIGS. 4A and 4B, but in other embodiments, the light-emitting devices 100 as discussed previously with respect to FIGS. 1A and 1B, or the light-emitting devices 200 as discussed previously with respect to FIGS. 2A and 2B may be utilized. As shown in FIGS. 4A and 4B, the light-emitting devices 300 may be arranged in a matrix of one or more rows and one or more columns, or in another systematic form in the two-dimensional plane of the substrate 470. As the large-scale electronic display 400 may be placed at outdoor, the light-emitting devices 300 may be covered using a dark potting agent 482. The dark potting agent 482 be arranged to protect the electronics component from moisture and to prevent reflection of light by the flat substrate 470. Each light-emitting device 300 may represent a pixel 480 of the display, but in another embodiment, a pixel may be represented by a plurality of light-emitting devices 300.

Different aspects, embodiments or implementations may, but need not, yield one or more of the following advantages. For example, high contrast ratio may be achieved when the light-emitting devices being arranged in an array form in a large-scale electronic display. Another advantage may be that lower cost might be achieved.

Although specific embodiments of the invention have been described and illustrated herein above, the invention should not be limited to any specific forms or arrangements of parts so described and illustrated. For example, light source die described above may be LEDs die or some other future light source die as known or later developed without departing from the spirit of the invention. Likewise, although light-emitting devices were discussed, the embodiments are applicable to component level such as a light-source packaging to produce the light-emitting devices. The scope of the invention is to be defined by the claims appended hereto and their equivalents.

What is claimed is:

1. A light-emitting device, comprising
a body having a base portion;
a plurality of conductors, a portion of the conductors being located on the base portion;
at least one light source die attached on a portion of one of the conductors adapted to accommodate the light source die; and
a dark layer characterized by a dark visual appearance arranged adjacent to the light source die on the base portion for absorbing light falling thereon.

2. The light-emitting device of claim 1, wherein the dark layer substantially occludes the portion of the plurality of conductors located on the base portion.

3. The light-emitting device of claim 1, wherein the dark layer is configured to occlude the base portion, substantially inhibiting the base portion from reflecting light.

4. The light-emitting device of claim 1, wherein the dark layer comprises black pigment.

5. The light-emitting device of claim 1, wherein the dark visual appearance of the dark layer is substantially black.

6. The light-emitting device of claim 1, wherein approximately ninety percent of light falling onto the dark layer is absorbed.

7. The light-emitting device of claim 1, wherein the dark layer is in direct contact with the light source die.

8. The light-emitting device of claim 1, wherein the dark layer has a thickness that is approximately less than forty percent the height of the light source die.

9. The light-emitting device of claim 1 further comprising an encapsulant substantially encapsulating the dark layer, the light source die and at least part of the base portion.

10. The light-emitting device of claim 1, wherein the at least one light source die is a top emitting die configured to emit light substantially in a direction approximately perpendicular to the base portion.

11. The light-emitting device of claim 1, wherein the body is substantially dark but lighter than the dark visual appearance of the dark layer.

12. The light-emitting device of claim 1, wherein the body comprises a printed circuit board.

13. The light-emitting device of claim 1, wherein the body further comprises at least a sidewall having an inner surface arranged substantially perpendicular to the base portion.

14. The light-emitting device of claim 13, wherein the at least one sidewall is substantially non-reflective.

15. The light-emitting device of claim 1, wherein the light-emitting device is adapted to form a portion of an electronic display.

16. A light source, comprising:
a body having a surface and at least one sidewall;
a cavity defined by the surface and the at least one sidewall;
a light source die configured to emit light, the light source die being disposed within the cavity on the surface of the body;
an aperture directly connecting the cavity externally for light emission;
a dark layer characterized by a dark visual appearance and arranged within the cavity adjacent to the light source die for absorbing light; and
an encapsulant substantially encapsulating the light source die, the surface and the dark layer within the cavity.

17. The light source of claim 16, wherein the at least one cavity sidewall comprises an inner surface arranged substantially perpendicular to the surface.

18. The light source of claim 16 further comprising a plurality of leads arranged with a portion of the leads disposed on the surface, wherein the dark layer is arranged to occlude light from falling on the portion of the leads disposed on the surface.

19. The light source of claim 16, wherein the dark layer is in direct contact with the light source die.

20. An electronic display system, comprising:
a substrate;
a plurality of light-emitting devices attached on the substrate;
a flat surface located on each of the light-emitting devices;
at least one light source die located on the flat surface; and
a dark layer adjacent to the light source die covering the flat surface to occlude the flat surface from light.
